(19) United States
(12) Patent Application Publication
(10) Pub. No.: US 2025/0055488 A1
(43) Pub. Date: Feb. 13, 2025

(54) CELLULAR NETWORK THAT SCALES TRANSMIT POWER BASED ON LINK CAPACITY AND MEASURED SNR

(71) Applicant: TalkingHeads Wireless, Inc., Roslindale, MA (US)

(72) Inventors: Mark A. BRIFFA, Tyreso (SE); Joel L. DAWSON, Roslindale, MA (US)

(73) Assignee: TalkingHeads Wireless, Inc., Roslindale, MA (US)

(21) Appl. No.: 18/666,144

(22) Filed: May 16, 2024

Related U.S. Application Data
(63) Continuation of application No. 17/525,392, filed on Nov. 12, 2021, now Pat. No. 11,990,926.
(60) Provisional application No. 63/112,515, filed on Nov. 11, 2020.
(60) Provisional application No. 63/112,534, filed on Nov. 11, 2020.
(60) Provisional application No. 63/112,526, filed on Nov. 11, 2020.
(60) Provisional application No. 63/112,542, filed on Nov. 11, 2020.

(51) Int. Cl. H04B 1/04; H03F 3/24; H04W 52/24; H04W 88/08

(52) U.S. Cl. CPC H04B 1/0483; H03F 3/245; H04W 52/241; H03F 2200/451; H04B 2001/045; H04W 88/085

(57) ABSTRACT

Described are concepts, systems and techniques for detecting whether an antenna is connected to a transmit system to thereby protect a power amplifier lineup from damage.

### RELATED APPLICATIONS

This application is a continuation of nonprovisional application Ser. No. 17/525,392 filed on Nov. 12, 2021 which claims the benefit under 35 U.S.C. § 119 (e) of: provisional application No. 63/112,515 filed on Nov. 11, 2020; provisional application No. 63/112,534 filed on Nov. 11, 2020; provisional application No. 63/112,526 filed on Nov. 11, 2020; and provisional application No. 63/112,542 filed on Nov. 11, 2020 all of which are hereby incorporated herein by reference in their entireties.

### BACKGROUND

The increase in the number and use of mobile communication networks (e.g. cellular networks) has led to a corresponding increase in the power consumption of mobile communication networks. It would, therefore, be desirable to provide systems and techniques to address power consumption concerns without reducing quality of service in mobile communication networks.

### SUMMARY

Based upon a measured signal-to-noise (SNR) on any given link in a cell, the upper limit of channel capacity is known (Shannon limit). Also, based upon a selected coding strategy implemented in a network and the measured SNR, the maximum realizable capacity may be determined. Furthermore, an actual achieved bit rate is known. In accordance with the concepts described herein, the inventors have recognized the SNR required to achieve a certain bit rate in a network can be determined from known performance metrics for a known coding strategy used in the network. It has also been recognized that if a measured SNR exceeds a “required” SNR, the difference between the two may be considered an “excess” SNR. It has also been recognized that this excess SNR corresponds to an amount of transmitter power which is in excess of that needed to produce an SNR which allows a link to achieve the certain bit rate. That is, it is possible to maintain an actual achieved bit rate while reducing a transmit power level of a base station. In accordance with the concepts described herein, it has been recognized that from measurable performance metrics of a network or portions of a network, one can determine an amount of excess SNR that exists and thus how much excess base station transmit power exists. In accordance with a further aspect of the concepts, systems and techniques described herein, in response to a known actual bit rate achieved in a cellular network, the cellular network may be configured to dynamically scale a power level of a radio.

Moreover, in embodiments, feedback mechanisms may be used to improve cellular network performance. Some feedback mechanisms which can be used in accordance with the concepts, systems and techniques described herein include, but are not limited to: (1) real-time measurements of achieved bit rate, and effective MIMO rank (this leads to a maximally adaptable cellular network); and long-term network statistics. In embodiments, either type of feedback (or even multiple types of feedback) may be used (either individually or in combination). This may result in an increase in the overall efficiency and lower the energy consumption of an RRH over its lifetime. The results in lower operating costs.

Other feedback mechanisms which can be used include, but are not limited to: (1) real-time measurements of SNR, and/or monitoring the dynamic coding decisions made in the network that determine the peak-to-average power ratio (PAPR) for each RRH pipe; and/or long-term network statistics. Either feedback mechanism may be used individually, or these feedback mechanisms may be used in combination.

In accordance with a further aspect of the concepts, systems and techniques disclosed herein, described is an additional use of multiple antennas, namely: divide a communication channel so that no single RF power amplifier in an RRH has to carry so much bandwidth that it cannot be efficiently operated (e.g. biased in a way that the PA efficiency is relatively high compared with a maximum efficiency achievable with the PA.

In theory, the channel capacity scales linearly with the number of MIMO paths. In practice, channel capacity grows much slower (˜square root).

In accordance with the concepts, systems and techniques described herein, it has been recognized that frequency bandwidth is always important/critical for high-capacity networks. However, it is also recognized that high bandwidth in RF systems leads to low efficiencies. This results in RRHs that are large, heavy, and expensive to operate.

To address these issues, described are concepts, systems and techniques which allow for high frequency bandwidth and high capacity RRHs that are also small, light and relatively inexpensive compared with conventional RRHs.

This result is achieved by tuning each power amplifier (PA) path for different center frequencies, to allow for coverage of wide aggregate frequency bandwidths in a variety of deployed frequency bands (keeping in mind that channel capacity always goes linearly with bandwidth when the SNR is substantially above 0 dB). In embodiments, the bandwidth of each path is chosen to allow high efficiency operation of a PA in the RRH. When few frequency bands are deployed, there is the option to raise amplifier supply voltages (e.g. Vdds) to keep total output power high. It should be noted that in this context, “few” means that PAs tuned to certain center frequencies are turned off because the bands that they are centered for are not being used (e.g., PAs in one or more of paths 34a-34n in FIG. 7).

When many bands are deployed, PA bias voltages (e.g. PA supply voltages or Vdds) can be adjusted (e.g. lowered) to keep total output power constant. It should be noted that in this context “many” means that all or almost all of the PA paths (e.g., PAs in one or more of paths 34a-34n in FIG. 7).

In embodiments, MIMO rank is increased by adding more paths at a given frequency offset.

Some feedback mechanisms which can be used in accordance with the concepts, systems and techniques described herein include, but are not limited to: (1) real-time measurements of achieved bit rate, and effective MIMO rank (this leads to a maximally adaptable cellular network); and long-term network statistics. In embodiments, either type of feedback (or even multiple types of feedback) may be used (either individually or in combination).

Some benefits of these concepts, systems and techniques include, but are not limited to an increase in the overall efficiency and lower the energy consumption of the RRH over its lifetime. The results in lower operating costs.

Other feedback mechanisms which can be used in accordance with the concepts, systems and techniques described herein include, but are not limited to: (1) real-time measurements of SNR, and/or monitoring the dynamic coding decisions made in the network that determine the peak-to-average power ratio (PAPR) for each RRH pipe; and/or long-term network statistics. Either feedback mechanism may be used or these feedback mechanisms may be used in combination.

Based upon a measured signal-to-noise (SNR) on any given link in a cell, the upper limit of channel capacity is known (Shannon limit). Also, based upon a selected coding strategy implemented in a network and the measured SNR, the maximum realizable capacity may be determined. Furthermore, an actual achieved bit rate is known.

In accordance with the concepts described herein, it has been recognized that from these data, it can be determined how much excess SNR exists. Known performance metrics of the coding strategy tell us how much SNR are needed to achieve a certain bit rate. If the measured SNR exceeds this “needed” SNR, the difference between the two is the excess SNR. It has also been recognized that this excess SNR corresponds to an amount of excess transmitter power. That is, it is possible to maintain the same actual achieved bit rate while reducing a transmit power level of a base station.

In accordance with a further aspect of the concepts, system and techniques described herein, in response to a known actual bit rate achieved in a cellular network, a cellular network is configured to dynamically scale a transmitted output power to an amount of transmitted output power which is substantially at or near a minimum amount of transmit power needed (ideally, at all times) to maintain an achieved bit rate.

With this particular arrangement, the power consumption of a transmit system may be reduced (or ideally minimized). In embodiments, by transmitting an output power which is substantially at or near a minimum amount of transmit power needed to maintain the known actual bit rate, power consumption of a transmit system can be reduced below the power consumption used in a conventional system. Furthermore, by transmitting an output power which is always at or near a minimum amount of transmit power needed to always maintain the known actual bit rate, the power consumption of a transmit system may be minimized.

In embodiments, the RF lineup (and in particular the RF power amplifier in a transmit system, can be dynamically scaled to keep the efficiency high. In embodiments, a transmit system may be provided as part of a transmit-receive (T/R) circuit (i.e. a soc-called T/R module).

In embodiments, by observing long-term statistics, it is possible to design a remote radio head (RRH) and/or active antennas to have a form factor which is smaller than the form factor of a conventional RRH. This is possible since, in accordance with the concepts described herein, the RRH may be designed to satisfy needs derived from observing long-term statistics, rather than always preparing for the absolute worst case. This leads to smaller (in area and/or volume), lighter RRHs.

In embodiments, one feedback mechanism utilizes real-time measurements of SNR, bit rate, and/or achieved capacity. Designing networks, systems and components in accordance with the concepts described herein leads to an adaptable cellular network and ideally leads to a maximally adaptable cellular network.

In embodiments, one feedback mechanism is feedback based upon long-term network statistics.

In embodiments, multiple feedback mechanisms can be used. For example, in embodiments, real-time measurements of SNR and/or bit rate and/or achieved capacity and/or long-term network statistics can be used. In embodiments, the some or all of the above feedback mechanisms can be used alone or can be used in combination.

Thus, systems and techniques designed, manufactured and operated in accordance with the concepts and techniques described herein address power consumption concerns without reducing quality of service in mobile communication networks.

In accordance with a still further aspect of the concepts described herein, a system for configuring a cellular network or one or more components thereof to dynamically scale a transmitted output power of a base station, the system comprising: a processor configured to: determine an actual achieved bit rate for a link in a cell of a cellular network; determine how much excess signal to noise ratio (SNR) exists within the cellular network; determine an amount of transmitted output power substantially corresponding to an amount of transmit power needed to maintain a selected bit rate; and configure the cellular network to dynamically scale to the determined amount of transmitted output power which is substantially at or near a minimum amount of transmit power needed at all times to maintain the selected bit rate.

In embodiments, the selected bit rate is one of an achieved bit rate or a desired bit rate.

In embodiments, the processor is further configured to determine an amount of transmitted output power substantially corresponding to an amount of transmit power needed to maintain at all times a selected bit rate.

In embodiments, the selected bit rate is one of an achieved bit rate or a desired bit rate.

In accordance with a still further aspect of the concepts described herein, a method for configuring a cellular network or one or more components thereof to dynamically scale a transmitted output power to an amount of transmitted output power which is substantially at or near a minimum amount of transmit power needed at all times to maintain a desired bit rate, the method comprising: determining an actual achieved bit rate for a link in a cell of a cellular network determining how much excess signal to noise ratio (SNR) exists within the cellular network; determining an amount of transmitted output power which is substantially at or near a minimum amount of transmit power needed at all times to maintain a selected bit rate; and configuring the cellular network to dynamically scale to the determined amount of transmitted output power which is substantially at or near a minimum amount of transmit power needed at all times to maintain the selected bit rate.

In embodiments, the selected bit rate is one of an achieved bit rate or a desired bit rate.

In embodiments, the processor is configured to determine an amount of transmitted output power substantially corresponding to an amount of transmit power needed to maintain at all times a selected bit rate.

In embodiments, the selected bit rate is one of an achieved bit rate or a desired bit rate.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1 is a block diagram of an example wireless communication system including a base station and one or more remote radio heads;

FIG. 2 is a schematic diagram of an illustrative mechanical switch having a spring-loaded contact arranged so as to provide an indication of when an antenna is coupled to a remote radio head;

FIG. 3 is a block diagram of radio frequency (RF) power amplifier (PA) lineups for a multiple-input, multiple-output (MIMO) RRH or active antenna;

FIG. 4 is a flow diagram of a process for dynamically scaling a transmitted output power to an amount of transmitted output power which is substantially at or near a minimum amount of transmit power needed at all times to maintain a desired bit rate;

FIG. 5 is a block diagram of a senor coupled between an output of a power amplifier and a bi-directional port of an antenna; and

FIG. 6 is a block diagram of a network having multiple cells.

### DETAILED DESCRIPTION

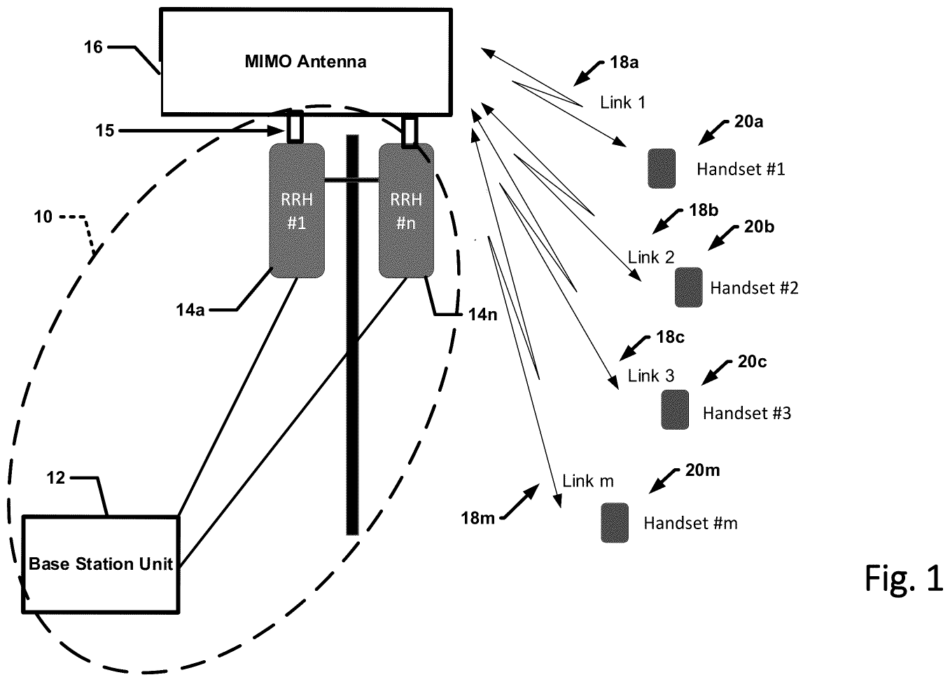

Referring now to FIG. 1, shown is an example cellular tower having one or more (here n) remote radio heads (RRHs) coupled thereto. Each RRH has one or more antenna coupled thereto at an RRH antenna port. A base station is in communication with the RRHs.

The RRHs may comprise one or more a transmit signal paths with each transmit signal path comprising one or more power amplifiers (PAS). The PAs can be severely damaged by turning on the heads (i.e. supplying RF power to a transmit signal path in the RRH) when one or more antennas are not connected to the RRH antenna port.

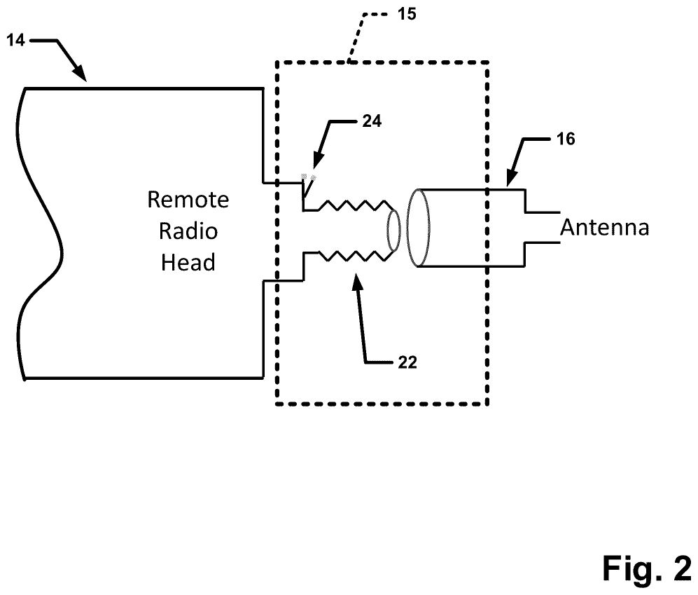

To address this issue, and referring now to FIG. 2, described is a mechanical means for detecting whether an antenna is electrically and/or mechanically connected to an RRH antenna port. In the example embodiment of FIG. 2, the means comprises a spring-loaded contact switch which provides a signal path having a substantially short circuit impedance characteristic when the antenna is fully coupled to the RRH antenna port and having a substantially open circuit impedance characteristic (or a high resistance signal path characteristic) when the antenna is not fully coupled to the RRH antenna port. As used herein, fully coupled means the antenna is (ideally) torqued to the right tension onto the antenna port connector.

Such mechanical means protects the PA (or a series of PAs or a PA lineup) from damage by preventing or otherwise disabling the RRH from powering on and/or by alerting a controller in the RRH that or more antennas is not coupled to an antenna port of an RRH. Such mechanical means of detecting may thus lower the risk of operating an RRH with a substantially open circuit impedance (also sometimes referred to herein simply as an open connection) at the antenna port of the RRH.

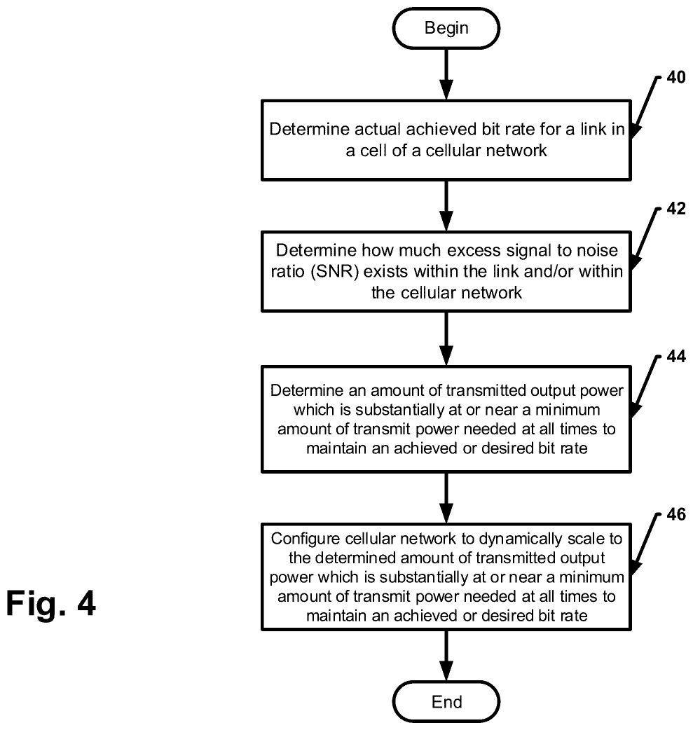

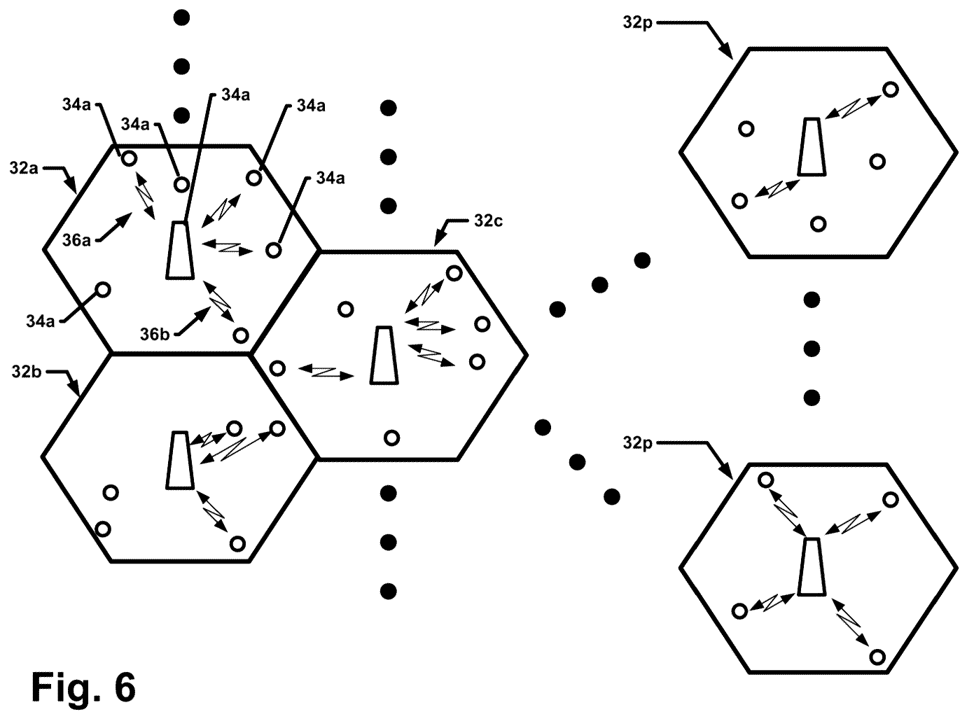

Furthermore, as will be described below in conjunction with FIGS. 4 and 6, in many systems, a circulator (or other protection circuit) may be coupled between the PA and the antenna. A circulator is a magnetic RF component which may be coupled between an output port of a PA and a port of the antenna and protects the PA from exposure to excess power reflected back to the PA output port. Such a reflection of power may be caused, for example, by a high voltage standing wave ratio (VSWR) condition (such as may be caused by an open circuit impedance) existing at an antenna port of an RRH. Thus, in accordance with the concepts described herein, it has been recognized that inclusion of mechanical means of detecting an unconnected antenna at an RRH antenna port may also allow relaxation of requirements (e.g. power handling requirements) of a circulator (or other protection circuit) coupled between the PA output port and an antenna.

Thus, at least some benefits of including a mechanical means of detecting whether an antenna is electrically and/or mechanically connected to an RRH antenna port, include, but are not limited to, relaxing the requirements of a circulator (e.g. technical and/or design requirements of a circulator) coupled between a PA output port and an antenna may enable lowering the insertion loss of the circulator.

Lowering the insertion loss of a circulator in a transmit signal path, in turn, raises the efficiency of the RF transmit signal path. Lowering the insertion loss of a circulator may also reduce the need for heatsinks in the RRH since portions of insertion lass energy may manifest itself as heat in the circulator.

Since high bandwidth in RF systems typically leads to low efficiencies (e.g. circulators and other components which having relatively high insertion loss characteristics requiring relatively large (and thus heavy) heat sinks or sophisticated cooling structures and/systems which may also be relatively large ad heavy), this results in RRHs that are large, heavy, and expensive to operate. Thus, utilization of mechanical means of detecting whether an antenna is electrically and/or mechanically connected to an RRH antenna port results in an RRH which is smaller and lighter than RRHs used in systems which do not include a mechanical means of detecting whether an antenna is electrically and/or mechanically connected to an RRH antenna port.

Referring again to FIG. 1, the cellular network comprises a base station unit coupled to one or more remote radio heads (RRHs) (with two RRHs being shown in FIG. 1) which in turn are coupled to one or more handsets (with m handsets being shown in FIG. 1) through an antenna. In embodiments, the antenna may be provided as a multiple-input, multiple-output (MIMO) antenna.

Based on a measured signal-to-noise (SNR) on any given link in the cell, the upper limit of channel capacity is known (Shannon limit). Based upon a selected coding strategy implemented in the network and the measured SNR, the maximum realizable capacity may be determined. Furthermore, an actual achieved bit rate is known. From these data, it can be determined how much “excess” SNR exists (with “excess” SNR being that amount of SNR which is above the amount to needed to continue communication at the actual achieved bit rate). It has also been recognized that such excess SNR corresponds to an amount of excess transmitter power. That is, it is possible to maintain the same actual achieved bit rate while reducing the amount of transit power.

In response to a known actual bit rate achieved in a cellular network, the cellular network is configured to dynamically scale a transmitted output power (e.g. base station output power) to an amount of transmitted output power which is substantially at or near a minimum amount of transmit power needed at all times to maintain an achieved (or desired) bit rate. In this way, the power consumption of a transmit system may be reduced (or ideally minimized).

In embodiments, by transmitting an output power which is substantially at or near a minimum amount of transmit power needed to maintain the known actual bit rate, power consumption of a transmit system can be reduced below the power consumption used in a conventional system. Furthermore, by transmitting an output power which is always at or near a minimum amount of transmit power needed to always maintain the known actual bit rate, the power consumption of a transmit system may be minimized.

In embodiments, the RF lineup (and in particular the RF power amplifier in a transmit system), can be dynamically scaled to keep the efficiency high. In embodiments, a transmit system may be provided as part of a transmit-receive (T/R) circuit (i.e. a soc-called T/R module).

In embodiments, by observing long-term statistics, it is possible to design a remote radio head (RRH) and/or active antennas to have a form factor which is smaller than the form factor of a conventional RRH. This is possible since, in accordance with the concepts described herein, the RRH may be designed to satisfy needs derived from observing long-term statistics, rather than always preparing for the absolute worst case. This leads to smaller (in area and/or volume), lighter RRHs.

In embodiments, one feedback mechanism utilizes real-time measurements of SNR, bit rate, and/or achieved capacity. Designing networks, systems and components in accordance with the concepts described herein leads to an adaptable cellular network and ideally leads to a maximally adaptable cellular network.

In embodiments, one feedback mechanism is feedback based upon long-term network statistics.

In embodiments, multiple feedback mechanisms can be used. For example, in embodiments, real-time measurements of SNR and/or bit rate and/or achieved capacity and/or long-term network statistics can be used. In embodiments, the some or all of the above feedback mechanisms can be used alone or can be used in combination.

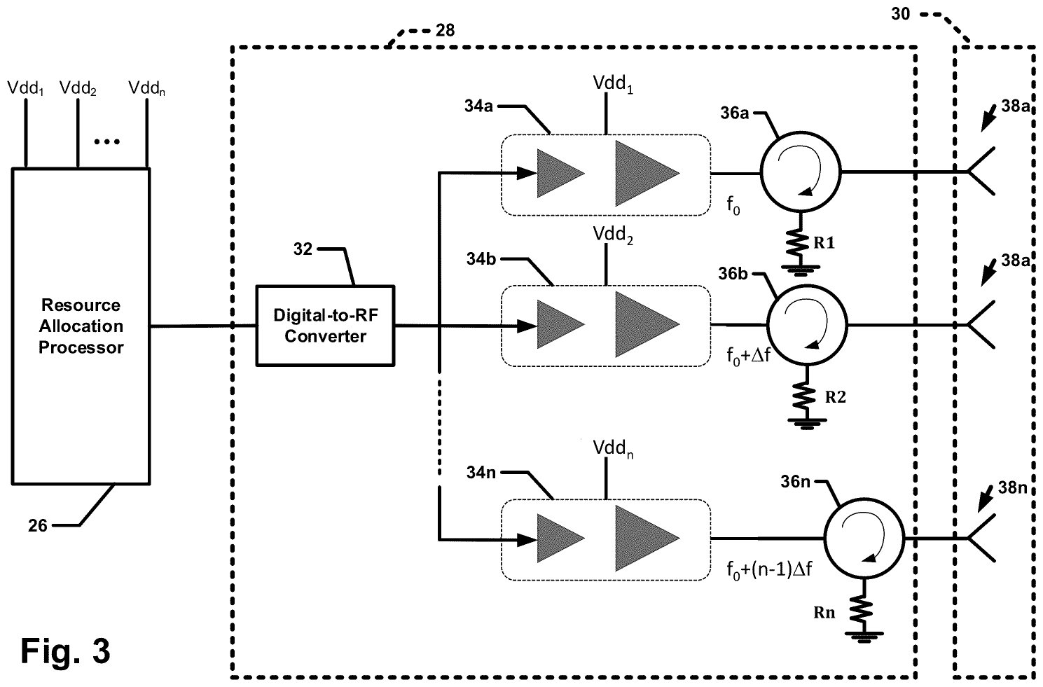

Referring now to FIG. 3, a system includes a resource allocation processor which receives all digital data to be transmitted, allocates the data to spectral ranges and provides signals (e.g. IQ signals) to a digital-to-RF converter. The resource allocation processor also receives and processes data provided to determine long-term signal statistics. In embodiments, such long-term signal statistics may include but are not limited to monitoring overall number of users; total bits/sec as a function of time in the whole network as well as over each individual link; real-time SNR in the link; effective MIMO rank.

The resource allocation processor may also provide amplifier supply voltages (e.g. Vdds) to supply terminals (or more generally bias terminals) of respective ones of a plurality of power amplifiers in response to the determined long-term signal statistics and in response thereto.

In accordance with determined signal frequencies from the resource allocation processor, the digital-to-RF converter provides appropriate RF signal to ones of a plurality of RF amplifier transmit paths (with n paths being shown in the example of FIG. 4).

Each power amplifier (PA) path may be tuned for operation at different center frequencies (e.g. frequencies at f₀, f₀+Δf, . . . f₀+(n−1) Δf) to allow for coverage of wide aggregate bandwidths in a variety of deployed bands (channel capacity varies substantially linearly with bandwidth). In embodiments, the bandwidth of each path is chosen to allow high efficiency. When few bands are deployed, there is the option to raise amplifier supply voltages (e.g. Vdds) to keep total output power high. When many bands are deployed, PA bias voltages (e.g. PA supply voltages or Vdds) can be adjusted (e.g. lowered) to keep total output power constant. In embodiments, MIMO rank may be increased by adding more paths at a given frequency offset.

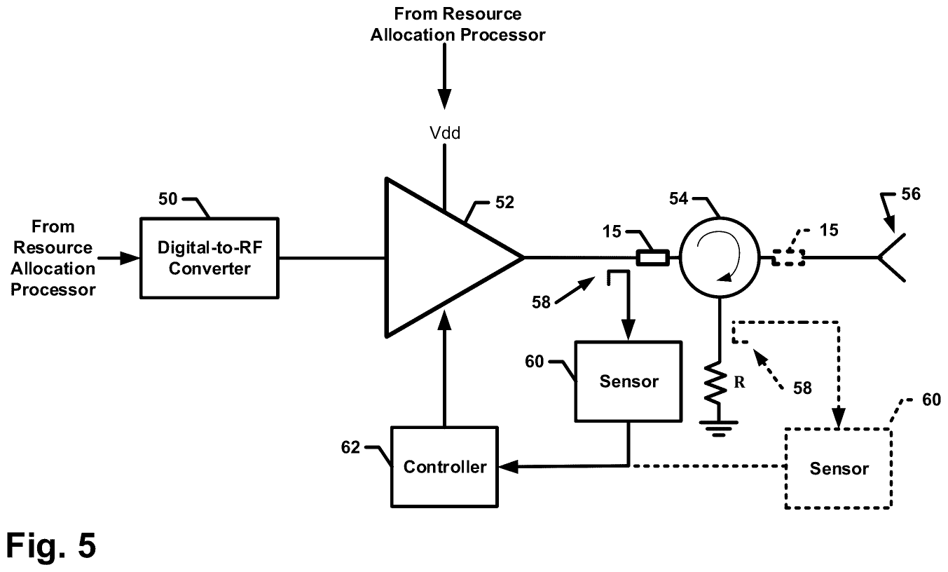

The output of the RF amplifier paths (each of which may comprise one or more amplifying devices) is coupled through a circulator (or other protection device) to an RF port of an antenna. The circulator protects RF amplifiers in the amplifier path from RF signals received by the antenna. The RF amplifiers may be protected from signals reflected at the port of the circulator coupled to the RF amplifier output port and propagated toward the output port of the RF amplifier in a manner to be described below in conjunction with FIG. 5.

The concepts, systems and techniques described herein allow for high bandwidth, high capacity RRHs that are also small and light.

Some feedback mechanisms which can be used in accordance with the concepts, systems and techniques described herein include, but are not limited to: (1) real-time measurements of achieved bit rate, and effective MIMO rank; and long-term network statistics.

It should be noted that use of effective MIMO rank may lead to a maximally adaptable cellular network. Effective MIMO rank is the measured parallelism actually achieved with a multiple antenna transmitter/receiver pair. The number of physical antennas tells you the potential MIMO rank that the hardware can handle. When the number of antennas that you have exceeds the effective MIMO rank (which is determined by, among other things, how cluttered the propagation path is by reflective objects), then the parallelism of those extra antennas is wasted.

In embodiments, either or even multiple types of feedback may be used (either individually or in combination).

Some benefits of these concepts, systems and techniques include, but are not limited to an increase in the overall efficiency and lower the energy consumption of the RRH over its lifetime. The results in lower operating costs.

Some feedback mechanisms which can be used in accordance with the concepts, systems and techniques described herein include, but are not limited to: (1) real-time measurements of SNR, and/or monitoring the dynamic coding decisions made in the network that determine the PAPR for each RRH pipe; and/or long-term network statistics. Long-term network statistics which may be used include, but are not limited to overall network traffic volume; measured SNR in any given link, and in all links; MIMO rank achieved. Either feedback mechanism may be used individually, or these feedback mechanisms may be used in combination.

Referring now to FIG. 4, a flow diagram of a process for dynamically scaling a transmitted output power to an amount of transmitted output power which is substantially at or near a minimum amount of transmit power needed at all times to maintain a desired bit rate includes determining an actual achieved bit rate for a link in a cell of a cellular network, determining an actual achieved bit rate for a link in a cell of a cellular network, determining how much excess signal to noise ratio (SNR) exists within the link and/or within the cellular network, determining an amount of transmitted output power which is substantially at or near a minimum amount of transmit power needed at all times to maintain an achieved or desired bit rate and configuring the cellular network to dynamically scale to the determined amount of transmitted output power which is substantially at or near a minimum amount of transmit power needed at all times to maintain an achieved or desired bit rate.

Referring now to FIG. 5, a digital-to-RF converter provides an RF signal to an input of an RF amplifier (e.g. an RF power amplifier). The output of the RF amplifier is coupled through a circulator (or other protection device) to an RF port of an antenna. An RF coupler (or other signal sensing device) couples or otherwise detects a portion of any RF signals which are reflected from the input port of the circulator back and propagate toward the output port of the RF amplifier. Such reflected signals may be due, for example, due to an impedance mismatch between the output impedance of the RF amplifier and the input impedance of the circulator port to which the RF amplifier output port is coupled (i.e. an impedance mismatch (or difference) between the impedance at the output port of the RF amplifier and the impedance at the port of the circulator to which the RF amplifier output port is coupled).

A sensor (or detector) receives a signal from the coupler. If the magnitude of the signal received by the sensor (either in voltage or power) exceeds a predetermined threshold level, then the senor provides a signal to a controller which prevents the RF amplifier from being turned on (or if the RF amplifier is already turned on, the controller may turn off the RF amplifier. Such action(s) may be taken to prevent the RF amplifier by being damages due to exposure to an RF signal received at the RF amplifier output port (e.g. an RF signal reflected from the circulator back toward the RF amplifier.

Referring now to FIG. 6, a cellular network comprises a plurality of cells with each cell comprising one or more base stations and each base station coupled to one or more radio heads. In this illustrative embodiment, cellular network is illustrated as a GSM cellular network in which cells are deployed in substantially uniform hexagons with having a cell tower with at least one base station unit and one or more RRHs. RRHs may be located substantially at the center of each cell and have omnidirectional antennas. The one or more base stations and radio heads may be the same as or similar to the base station and radio heads described above in conjunction with at least FIGS. 1 and 4.

Although reference is made herein to particular systems or configurations, it is appreciated that other systems or configurations having similar functional and/or structural properties may be substituted where appropriate, and that a person having ordinary skill in the art would understand how to select such systems or configurations and incorporate them into embodiments which incorporate the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs.

The terms “one or more” and “more than one” are understood to include any integer number greater than or equal to one, i.e. one, two, three, four, etc. The term “a plurality” is understood to include any integer number greater than or equal to two, i.e. two, three, four, five, etc.

The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description herein, the terms “upper,” “lower,” “right,” “left,” “vertical,” “horizontal, “top,” “bottom,” and derivatives thereof shall relate to the described structures and methods, as oriented in the drawing figures.

The terms “overlying,” “atop,” “on top, “positioned on” or “positioned atop” mean that a first element, such as a first structure, is present on a second element, such as a second structure, where intervening elements such as an interface structure may or may not be present between the first element and the second element.

The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “substantially,” “approximately” and “about” may be used to mean within +20% of a target value in some embodiments, within +10% of a target value in some embodiments, within +5% of a target value in some embodiments, and yet within +2% of a target value in some embodiments. The terms “approximately” and “about” may include the target value. The term “substantially equal” and “approximately equal” may be used to refer to values that are within +20% of one another in some embodiments, within +10% of one another in some embodiments, within +5% of one another in some embodiments, and yet within +2% of one another in some embodiments.

The terms “substantially,” “approximately” and “about” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

1-12. (canceled)

13. A remote radio head (RRH) configured to communicate with a mobile unit over a wireless communication link, the RRH comprising:
at least one power amplifier (PA) configured to provide an amount of output power which is substantially at or near a minimum amount of output power required to maintain a selected bit rate between the RRH and the mobile unit via the wireless communication link.

14. The RRH of claim 13 wherein the PA has a maximum output power level which is substantially at or near a minimum amount of output power required to maintain the selected bit rate between the RRH and the mobile unit via the wireless communication link.

15. The RRH of claim 14 wherein the maximum output power level of the PA is determined based upon at least one or more of: an actual achieved bit rate for a link in a cell of a cellular network; an amount of excess signal to noise ratio (SNR) which exists within the link for the actual achieved bit rate.

16. The RRH of claim 13 wherein the selected bit rate is one of an achieved bit rate or a desired bit rate.

17. The RRH of claim 13 wherein the output power level of the PA is dynamically scaled to the determined amount of transmitted output power which is substantially at or near a minimum amount of transmit power needed at all times to maintain the selected bit rate.

18. The RRH of claim 17 further comprising means for receiving one or more control signals to dynamically scale an output power of the PA such that the PA is operated to provide an amount of transmitted output power substantially corresponding to an amount of transmit power needed to maintain the selected bit rate.

19. The RRH of claim 17 further comprising means for receiving one or more control signals to dynamically scale an output power of the PA such that the PA is operated to provide an amount of transmitted output power substantially corresponding to an amount of transmit power needed to maintain the selected bit rate at all times.

20. The system of claim 19 wherein the selected bit rate corresponds to an achieved bit rate.

21. An adaptable cellular network comprising:
a remote radio head (RRH) having a plurality of transmit signal paths with each transmit signal path comprising one or more power amplifiers and with each transmit signal path tuned for operation at different center frequency (f₀, f₀±Δf, . . . f₀±(n−1) Δf) where Δf is a frequency offset and n is an integer representing the number of transmit signal paths in the RRH and wherein each transmit signal path has an operational frequency bandwidth selected such that each power amplifier in the respective transmit signal path operates with high efficiency.

22. The system of claim 21 wherein the RRH determines how many of the n transmit signal paths to use to transmit information depending upon an amount of information to be transmitted and in response to the number of transmit paths being utilized, bias voltages to the one or more power amplifiers in each transmit signal path are adjusted to keep total output power substantially constant.

23. The adaptable cellular network of claim 22 wherein:
in response to less than n transmit signal paths being utilized by the RRH, bias voltages provided to power amplifiers in the utilized signal paths are raised; and
in response to n transmit signal paths being utilized by the RRH, bias voltages provided to power amplifiers in the utilized signal paths are lowered.

24. The adaptable cellular network of claim 21 further comprising one or more of:
a feedback mechanism for determining real-time measurements of SNR and for providing information corresponding to such real-time measurements of SNR to the RRH;
a feedback mechanism for real-time measurements of bit rate and for providing information corresponding to such real-time measurements of bit rate to the RRH;
a feedback mechanism for real-time measurements of achieved capacity and for providing information corresponding to such real-time measurements of achieved capacity to the RRH; and
a feedback mechanism for long-term network statistics and for providing information corresponding to such long-term network statistics to the RRH.

25. The adaptable cellular network of claim 21 further comprising one or more of:
a feedback mechanism for determining real-time measurements of SNR and for providing information corresponding to such real-time measurements of SNR to the RRH;
a feedback mechanism for real-time measurements of bit rate and for providing information corresponding to such real-time measurements of bit rate to the RRH;
a feedback mechanism for real-time measurements of achieved capacity and for providing information corresponding to such real-time measurements of achieved capacity to the RRH; and
a feedback mechanism for long-term network statistics and for providing information corresponding to such long-term network statistics to the RRH.

26. The adaptable cellular network of claim 21 further comprising a power management system coupled to the one or more power amplifiers, the power management system for adjusting a bias voltage provided to the one or more power amplifiers (PA) based upon signal statistics including but not limited to peak-to-average power ratios (PAPR).

27. The adaptable cellular network of claim 21 wherein the power management system is configured to adjust supply voltages provided to supply terminals of the one or more power amplifiers.

28. A cellular network comprising:
a base station;
one or more remote radio heads (RRHs) coupled to the base station;
one or more handsets in communication with at least some of the one or more RRHs over a wireless channel; and
wherein the one or more RRHs operate in response to a coding algorithm based upon expected or measured signal-to-noise (SNR) in the wireless channel.

29. The cellular network of claim 28 wherein the RRHs operate in accordance with a coding algorithm.

30. The cellular network of claim 29 wherein the coding algorithm is chosen based upon expected or measured signal-to-noise (SNR) in the wireless channel.

31. The cellular network of claim 29 wherein the coding algorithm is adjusted based upon expected or measured signal-to-noise (SNR) in the wireless channel.

32. The cellular network of claim 29 wherein for a given average output power, supply voltages for a PA lineup are selected based upon a density of symbol constellations wherein peak-to-average power ratios (PAPR) increase with increasing density of symbol constellations.
